(19) United States
(12) Patent Application Publication
(10) Pub. No.: US 2010/0127752 A1
(43) Pub. Date: May 27, 2010

(54) LEVEL SHIFTER WITH LOW VOLTAGE DEVICES

(75) Inventors: Jimmy Fort, Provence (FR); Michel Cuenca, France (FR); Emmanuel Racape, Aix-en-Provence (FR); Jean-Michel Daga, Peynier (FR)

Correspondence Address: FISH & RICHARDSON P.C., PO BOX 1022, MINNEAPOLIS, MN, 55440-1022, US

(73) Assignee: ATMEL Corporation, San Jose, CA (US)

(21) Appl. No.: 12/277,024

(22) Filed: Nov. 24, 2008

(51) Int. Cl. H03L 5/00

(52) U.S. Cl. 327/333

(57) ABSTRACT

A voltage level shifter is disclosed that includes low voltage devices. In some implementations, a voltage level shifter having a differential structure includes low voltage, complementary N-channel metal oxide semiconductor (NMOS) input transistors and low voltage, complementary cross-coupled P-channel metal oxide semiconductor (PMOS) output transistors. One or more complementary NMOS/PMOS series intermediate transistor pairs are interposed between respective drains of the NMOS transistors and PMOS transistors to limit high voltage drops across the NMOS input transistors and PMOS output transistors. In some implementations, each intermediate transistor pair is biased by a single intermediate voltage. The sources of the low voltage devices are connect to a bulk/substrate. The complementary outputs of the level shifter can be taken from the drains of the NMOS/PMOS series intermediate transistor pairs.

### TECHNICAL FIELD

This subject matter relates generally to electronic circuits, and more particularly to voltage level shifters for use in flash memories and other devices which require high voltage management.

### BACKGROUND

Conventional flash memories use high voltage devices to manage a high supply voltage. The circuitry of the flash memories includes charge pump circuits and level shifters. The charge pump circuits and level shifters often include high voltage transistors that require additional masks during fabrication. The additional masks can add additional costs to the manufacturing process.

### SUMMARY

A voltage level shifter is disclosed that includes low voltage devices. In some implementations, a voltage level shifter having a differential structure includes low voltage, complementary N-channel metal oxide semiconductor (NMOS) input transistors and low voltage, complementary cross-coupled P-channel metal oxide semiconductor (PMOS) output transistors. One or more complementary NMOS/PMOS series intermediate transistor pairs are interposed between respective drains of the NMOS transistors and PMOS transistors to limit high voltage drops across the NMOS input transistors and PMOS output transistors. In some implementations, each intermediate transistor pair is biased by a single intermediate voltage. The sources of the low voltage devices are connect to a bulk/substrate. The complementary outputs of the level shifter can be taken from the drains of the NMOS/PMOS series intermediate transistor pairs. The basic level shifter circuit described above can be replicated and added to output stages to create additional level shifter circuits that are capable of providing higher voltage differences.

Advantages of the disclosed voltage level shifters with low voltage devices include, but are not limited, reduced fabrication costs through the use of standard process devices and the elimination of additional masks associated with high voltage device fabrication.

### BRIEF DESCRIPTION OF THE DRAWINGS

FIG. 1 is a schematic diagram of an example conventional level shifter circuit including high voltage devices.

FIG. 2 is a schematic diagram of an example 2VDD level shifter circuit with low voltage devices.

FIG. 3 is a schematic diagram of an example 3VDD level shifter circuit with low voltage devices.

FIG. 4 is a schematic diagram of an example 4VDD level shifter circuit with low voltage devices.

FIG. 5 is a schematic diagram of an example 5VDD level shifter circuit with low voltage devices.

FIG. 6 is block diagram illustrating how a 4VDD level shifter can be extended to (N)VDD.

### DETAILED DESCRIPTION

### Example Voltage Level Shifter with High Voltage Devices

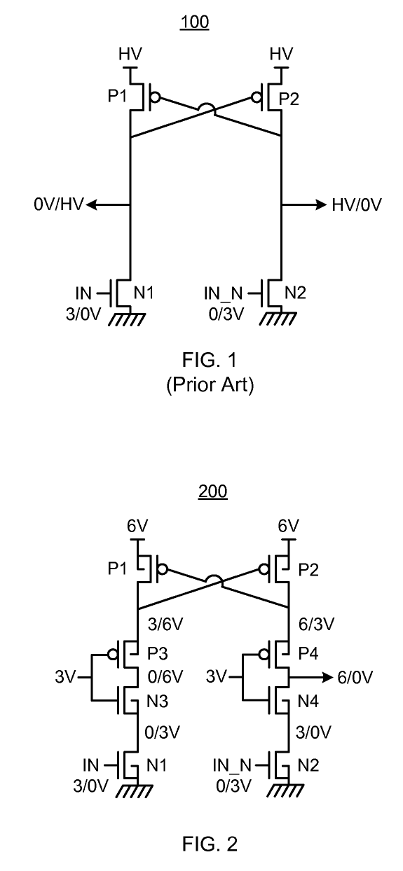

FIG. 1 is a schematic diagram of an example conventional level shifter circuit 100 with high voltage (HV) devices. For FIGS. 1-6, the annotation V1/V2 shown at a node of a level shifter circuit is interpreted as follows: V1 is a voltage given by a logic input and V2 is a voltage given by the complementary logic input. In FIG. 1, for example, if V1=3 volts, then V2=0 volts. To perform read, program and erase operations in embedded flash memory, it is often necessary to apply high voltages (e.g., higher than a typical control logic voltage supply) to the flash cell. A voltage level shifter takes a low voltage supply VDD and shifts it to a higher voltage, such as 2*VDD, 3*VDD, 4*VDD, and so forth.

The conventional voltage level shifter circuit 100 shown in FIG. 1 has a differential structure and uses complementary, cross-coupled PMOS output transistors P1, P2, and complimentary NMOS input transistors N1, N2, respectively. The gates of the input transistors N1, N2 receive complementary input voltages IN and IN_N (e.g., 3/0V, 0/3V) and the drains of the output transistors P1, P2 provide complementary, level-shifted output voltages (0V/HV, HV/0V).

The transistors P1, P2, N1 and N2 are all high voltage devices. In the voltage level shifter circuit 100, the maximum voltage difference between the nodes of transistors P1, P2, N1, N2 is the voltage applied on HV, which can be higher than 15V. The high voltage transistors P1, P2, N1, N2 must be processed to sustain HV if HV exceeds the break down voltage of the transistors P1, P2, N1, N2 (e.g., Max 5V for 70A transistor). Such processes increase complexity and cost through the use of additional masks and process steps.

### Example Voltage Level Shifters with Low Voltage Devices

FIG. 2 is a schematic diagram of an example 2VDD level shifter circuit 200 with low voltage devices. A first branch (left branch) of the voltage level shifter circuit 200 includes a PMOS transistor P1 coupled in series with a PMOS/NMOS series intermediate transistor pair P3, N3, where “P” indicates a PMOS device and “N” indicates an NMOS device. The intermediate transistor pair P3, N3 is interposed between the drains of output transistor P1 and input transistor N1. A second branch (right branch) of the voltage level shifter circuit 200 includes an output transistor P2 coupled in series with a PMOS/NMOS series intermediate transistor pair P4, N4. The intermediate transistor pair P4, N4 is interposed between the drains of output transistor P2 and input transistor N2.

The output transistors P1, P2 are cross-coupled. The gates of input transistors N1, N2 receive complementary input voltages. The gates of the intermediate transistor pair P3, N3 are coupled to an intermediate bias voltage (e.g., 3V). In a shared-bias configuration, the gates of the intermediate transistor pair P4, N4 are also coupled to the intermediate bias voltage. The voltage source can be provided by, for example, a low voltage charge pump circuit. In some implementations, the intermediate transistor pairs can be configured in a split-bias configuration, where the PMOS transistor in the intermediate transistor pair is biased by a first bias voltage and the NMOS transistor in the intermediate transistor pair is biased by a second bias voltage.

In the voltage level shifter circuit 200, the maximum voltage difference has been reduced due to bias voltages applied to the intermediate transistor pairs. The source of each of the low voltage transistors used in the voltage level shifter circuit 200, including the transistors used in the intermediate transistor pairs is connected to the bulk or substrate to avoid voltage drops between bulk-drain, bulk-source and bulk-gate. A triple well process can be used to form these bulk connections.

The intermediate transistor pairs effectively limit a high voltage drop on the input transistors N1, N2 and output transistors P1 and P2 by maintaining their gates at a specified bias voltage (e.g., 3V). For example, if IN=3V, the source of transistor N3 is set to 0V by transistor N1 and the drain of transistor P3 is set to 0V by transistor N3. The transistor P3 prevents the voltage level on the drain of P1 from dropping to 0V which could damage transistor P1. Transistor P3 allows discharge of the drain of transistor P1 until the gate voltage of transistor P3 (e.g., 3V) is reached (the transistor is OFF; vgs=0V). The use of transistor N3 in the intermediate transistor pair can be explained by applying IN=0V. With this input voltage, transistor N3 prevents the voltage level on the drain of transistor N1 from being set higher than the gate voltage of transistor N3 (3V instead of 6V). The output voltages can be tapped from the drains of the transistors of the intermediate transistor pairs. For example, 6/0V output voltages can be tapped from the drains of transistors P4, N4, which have been coupled together.

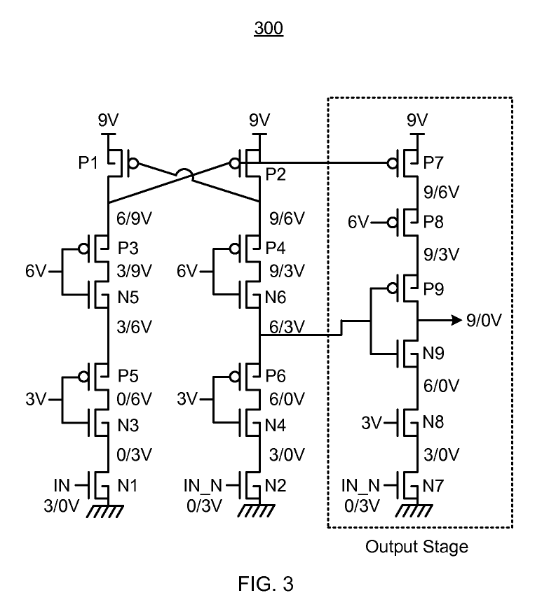

The basic level shifter circuit 200 can be replicated and combined with output stages to create additional voltage level shifter circuits with higher voltage differences, as described in reference to FIGS. 3-6.

FIG. 3 is a schematic diagram of an example 3VDD level shifter circuit 300 with low voltage devices. In a first branch (left branch) two intermediate transistor pairs P3, P5 and N3, N5 are interposed between the drains of output transistor P1 and input transistor N1. The gates of P3 and N5 are coupled to first intermediate bias voltage (e.g., 6V). The gates of P5 and N3 are coupled to a second intermediate bias voltage (e.g., 3V). The source of all transistors is connected to the bulk. An output stage is added to generate an output voltage at 9V or 0V because this combination of voltages is not directly available on the core circuit. On each of the branches the maximum voltage drop is equal to VDD.

In some implementations, the output stage is a single branch that includes transistors P7, P8, P9, N9, N8 and N7 coupled in series. The gate of P7 is coupled to the gate of transistor P2. The gates of transistors P9 and N9 are coupled to the sources of transistors P6 and N6. The gate transistor P8 is coupled to a 6V intermediate bias voltage and the gate of N8 is coupled to a 3V intermediate bias voltage. The output voltage can be tapped from the drains of P9 and N9, which are coupled together.

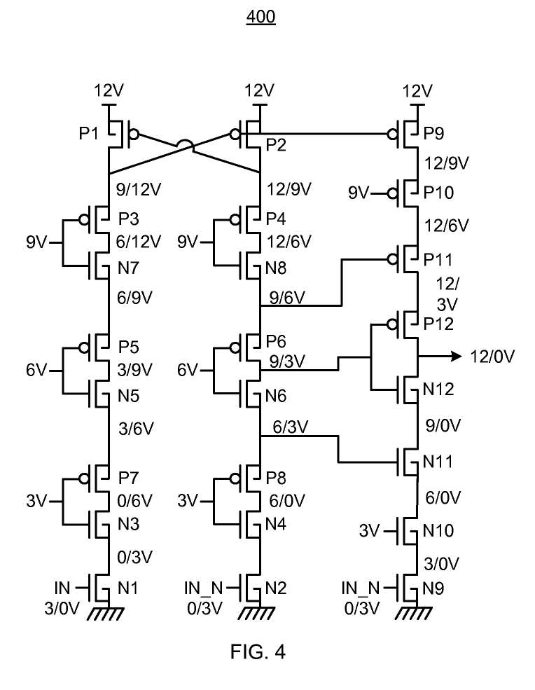

FIG. 4 is a schematic diagram of an example 4VDD level shifter circuit 400 with low voltage devices. The level shifter circuit 400 uses the same output stage as the level shifter circuit 300. The sources of all transistors used in circuit 400 are connected to the bulk.

A first branch (left branch) includes output transistor P1 and input transistor N1 with intermediate transistor pairs P3/N7, P5/N5 and P7/N3 interposed between the drains of transistor P1 and transistor N1. A second branch (right branch) includes output transistor P2 and input N2 with intermediate transistor pairs P4/N8, P6/N6, and P8/N4 interposed between the drains of output transistor P2 and input transistor N2.

The output stage includes a single branch with series coupled transistors P9, P10, P11, P12, N12, N11, N10 and N9. The gate of transistor P9 is coupled to the gate of transistor P2, the gate of transistor P11 is coupled to the sources of transistors N8 and P6, the gates of transistors P12 and N12 are coupled to the sources of transistors P6 and N6. An output voltage can be tapped from the drains of transistors P12, N12 in the output stage. All of the transistors in circuit 400 have their sources connected to the bulk.

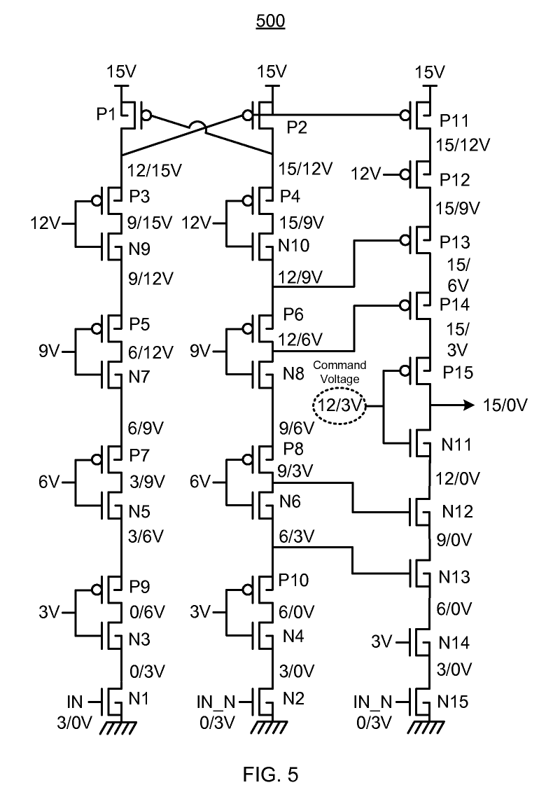

FIG. 5 is a schematic diagram of an example 5VDD level shifter circuit 500 with low voltage devices. In circuit 500, the previous 4VDD stage is used to control the output gate voltage. A first branch (left branch) includes output transistor P1 and input N1 with intermediate transistor pairs P3/N9, P5/N7, P7/N5, P9/N3, interposed between the drains of output transistor P1 and input N1. A second branch (right branch) includes output transistor P2 and input transistor N2 with intermediate transistor pairs P4/N10, P6/N8, P8/N6, P10/N4 interposed between the drains of output transistor P2 and input transistor N2. The sources of all transistors in circuit 500 are coupled to the bulk. An output voltage (e.g., 15/0V) can be tapped from the drains of transistors P15, N11.

The output stage includes a single branch of series coupled transistors P11, P12, P13, P14, P15, N11, N12, N13, N14 and N15. The gate of transistor P11 is coupled to the gate of output transistor P2. The gate of transistor P13 is coupled to the sources of transistors P6 and N10, which are coupled together. The gate of transistor N12 is coupled to the drains of transistors P8 and N6, which are coupled together. The gate of transistor N13 is coupled to the sources of transistors N6 and P10, which are coupled together.

In circuit 500, a command voltage 12V/3V is applied on the gates of transistors P15 and N11. This command voltage can be generated by the 4VDD level shifter circuit 400, described in reference to FIG. 4. The circuit 400 can be used in a cascade to create additional level shifter circuits with higher voltage drops, such as 6VDD, 7VDD, 8VDD and so forth.

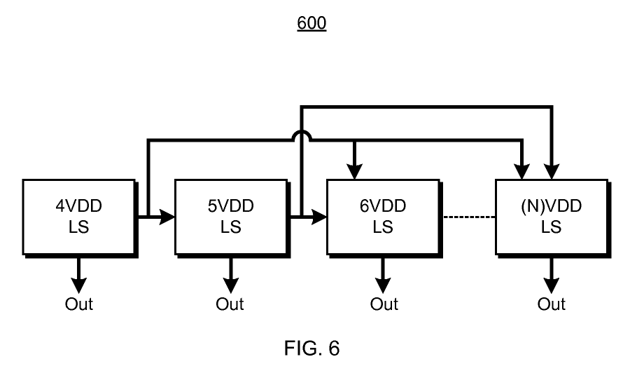

FIG. 6 is block diagram illustrating how the 4VDD level shifter circuit 400 can be extended to (N)VDD. An output voltage of the 4VDD level shifter circuit 400 can be used as a command voltage in 5VDD, 6VDD . . . (N)VDD level shifter circuits. Similarly, an output voltage of the 5VDD level shifter circuit 500 can be used as a command voltage in the 6VDD . . . (N)VDD level shifter circuits and so forth.

The impact on the structure size of the level shifter circuits due to the intermediate transistor pairs is balanced by the reduced size of the standard devices compared to high voltage devices used in the conventional level shifter circuit 100 of FIG. 1. The limitation of the structure is the drop voltage between the well and the substrate if the voltage is increased too much. Extending this approach to the overall high voltage management of flash memory would result in noticeable embedded flash process cost savings, and simplified integration into base line CMOS processes. Moreover, the use of this structure is not limited only to flash memories but is also applicable to any circuit that requires high voltage management.

1. A voltage level shifter circuit formed on a substrate, comprising:
a pair of complementary, low voltage input transistors;
a pair of complementary, low voltage, cross-coupled output transistors; and
one or more intermediate transistor pairs interposed between drains of the input transistor pair and the output transistor pair, the one or more intermediate transistor pairs operable for biasing the drains of the input transistor pair and output transistor pair to prevent the drains from discharging to voltage levels that exceed a specified voltage level, wherein the sources of the input transistor pair, output transistor pair and the one or more intermediate transistor pairs are connected to the substrate, and the drains of at least one intermediate transistor pair provides complementary output voltages.

2. The circuit of claim 1, where at least one intermediate transistor pair includes a PMOS transistor and NMOS transistor coupled in series and having gates coupled to a shared intermediate bias voltage.

3. The circuit of claim 1, where the input transistor pair are N-channel metal oxide semiconductor (NMOS) transistors and the output device pair are P-channel metal oxide semiconductor (PMOS) transistors.

4. The circuit of claim 1, further comprising an output stage coupled to the output transistor pair, the output stage including additional transistors coupled in series that are operable to generate additional output voltages that are not directly available from the level shifter circuit.

5. A voltage level shifter circuit formed on substrate, comprising:
a first branch including:
a first P-channel metal oxide semiconductor (PMOS) inverted output transistor having a source, drain and gate;
a first PMOS inverted intermediate transistor having a source, drain and gate, the first PMOS inverted intermediate transistor source coupled to the drain of the first PMOS inverted output transistor;
a first N-channel metal oxide semiconductor (NMOS) non-inverted intermediate transistor having a source, drain and gate, the drain coupled to the drain of the first inverted intermediate PMOS intermediate transistor;
a first NMOS non-inverted input transistor having a source, drain and gate, the drain coupled to the source of the first NMOS non-inverted intermediate transistor;
a second branch including:
a second PMOS inverted output transistor having a source, drain and gate, the gate coupled to the drain of the first PMOS inverted output transistor, the drain coupled to the gate of the first PMOS inverted output transistor;
a second PMOS inverted intermediate transistor having a source, drain and gate, the second PMOS inverted intermediate transistor source coupled the drain of the second PMOS inverted output transistor;
a second NMOS non-inverted intermediate transistor having a source, drain and gate, the drain coupled to the drain of the second inverted intermediate PMOS intermediate transistor; and
a second NMOS non-inverted input transistor having a source, drain and gate, the drain coupled to the source of the second NMOS non-inverted intermediate transistor,
wherein the sources of all the transistors in the level shifter circuit are coupled to the substrate, and wherein drains of the intermediate transistors are operable to provide complementary output voltages.

6. The circuit of claim 5, wherein gates of the first PMOS inverted intermediate transistor and the first NMOS non-inverted intermediate transistor are coupled together and operable for receiving a first bias voltage, and wherein gates of the second PMOS inverted intermediate transistor and the second NMOS non-inverted intermediate transistor are coupled together and operable for receiving a second bias voltage.

7. The circuit of claim 6, where the first and second bias voltages are coupled to a common bias voltage source.
